(19) United States
(12) Patent Application Publication
(10) Pub. No.: US 2025/0379092 A1
(43) Pub. Date: Dec. 11, 2025

(54) METHOD OF MANUFACTURING SEMICONDUCTOR DEVICE

(71) Applicant: FUJI ELECTRIC CO., LTD., Kawasaki-shi (JP)

(72) Inventors: Michiya KITANO, Matsumoto-city (JP); Akira TAMENORI, Matsumoto-city (JP)

(73) Assignee: FUJI ELECTRIC CO., LTD., Kawasaki-shi (JP)

(21) Appl. No.: 19/193,382

(22) Filed: Apr. 29, 2025

(30) Foreign Application Priority Data
Jun. 7, 2024 (JP) 2024-093262

(51) Int. Cl. H01L 21/683; H01L 21/265; H01L 21/304

(52) U.S. Cl. CPC H01L 21/6836; H01L 21/26513; H01L 21/304; H01L 2221/68327

(57) ABSTRACT

A method of manufacturing a semiconductor device, including: preparing a semiconductor wafer having a front surface and a back surface opposite to each other, and forming a front-surface device structure at the front surface; grinding the semiconductor wafer from the back surface, thereby thinning the semiconductor wafer; forming a back-surface device structure at the back surface of the semiconductor wafer after the grinding; applying a protective tape to the back surface of the semiconductor wafer, thereby protecting the back-surface device structure; and performing a first ion-implantation process of ion-implanting a first dopant from the front surface of the semiconductor wafer while the back surface of the semiconductor wafer is held by a holding apparatus via the protective tape.

### CROSS REFERENCE TO RELATED APPLICATIONS

This application is based upon and claims the benefit of priority of the prior Japanese Patent Application No. 2024-093262, filed on Jun. 7, 2024, the entire contents of which are incorporated herein by reference.

### BACKGROUND OF THE INVENTION

### 1. Field of the Invention

Embodiments of the disclosure relate to a method of manufacturing a semiconductor device.

### 2. Description of the Related Art

Japanese Laid-Open Patent Publication No. 2015-207733 describes a technique that includes reducing the thickness of a wafer by back grinding the wafer to which surface processes have been completed and thereafter, performing ion implantation to a back surface of the wafer with a front surface of wafer being directly attached to a wafer stage. Japanese Laid-Open Patent Publication No. 2007-149974 describes a technique of using a protective tape for back grinding, as a protective tape for a front surface of a wafer when ion implantation is performed to a back surface of the wafer. Japanese Laid-Open Patent Publication No. 2006-324585 and International Publication No. WO 2008/120467 describe techniques of protecting a back side (side having a second main surface/second surface) of a substrate when ion implantation is performed to a front side (side having a first main surface/first surface) of the substrate. International Publication No. WO 2019/216085 describes a technique of performing ion implantation to a back surface of a wafer after the thickness of the wafer is reduced by back grinding.

### SUMMARY OF THE INVENTION

According to an embodiment of the present disclosure, a method of manufacturing a semiconductor device, the method including: preparing a semiconductor wafer having a front surface and a back surface opposite to each other, and forming a front-surface device structure at the front surface; grinding the semiconductor wafer from the back surface, thereby thinning the semiconductor wafer; forming a back-surface device structure at the back surface of the semiconductor wafer after the grinding; applying a protective tape to the back surface of the semiconductor wafer, thereby protecting the back-surface device structure; and performing a first ion-implantation process of ion-implanting a first dopant from the front surface of the semiconductor wafer while the back surface of the semiconductor wafer is held by a holding apparatus via the protective tape.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a flowchart showing an outline of a method of manufacturing a semiconductor device according to an embodiment.

FIG. 2 is a perspective view depicting a state of the semiconductor device during manufacture according to the embodiment.

FIG. 3 is a cross-sectional view depicting a state of the semiconductor device during manufacture according to the embodiment.

FIG. 4 is a cross-sectional view depicting another example of a state of the semiconductor device during manufacture according to the embodiment.

FIG. 5 is a perspective view depicting a state of the semiconductor device during manufacture according to the embodiment.

FIG. 6 is a perspective view depicting a state of the semiconductor device during manufacture according to the embodiment.

FIG. 7 is a perspective view depicting a state of the semiconductor device during manufacture according to the embodiment.

FIG. 8 is a perspective view depicting a state of the semiconductor device during manufacture according to the embodiment.

FIG. 9 is a cross-sectional view depicting a state of the semiconductor device during manufacture according to the embodiment.

### DETAILED DESCRIPTION OF THE INVENTION

First, problems associated with the conventional techniques are discussed. In Japanese Laid-Open Patent Publication No. 2015-207733, Japanese Laid-Open Patent Publication No. 2007-149974, Japanese Laid-Open Patent Publication No. 2006-324585, International Publication No. WO 2008/120467, and International Publication No. WO 2019/216085, when processes are performed with the back surface of the wafer being directly attached to the wafer stage after back grinding, dents (scratches, recesses), contamination, etc. occur at the back surface of the wafer and the rate of conforming products decreases.

An outline of an embodiment of the present disclosure is described. (1) A method of manufacturing a semiconductor device according to one aspect of the present disclosure includes the following. As a front surface process, forming a predetermined front-surface device structure at a front surface of a semiconductor wafer. As a grinding process, grinding the semiconductor wafer from a back surface thereof, thereby thinning the semiconductor wafer. As a back surface process, forming a predetermined back-surface device structure at the back surface of the semiconductor wafer after the back grinding. As a protecting process, applying a protective tape to the back surface of the semiconductor wafer, thereby, protecting the back-surface device structure. As a first ion-implantation process, ion-implanting a first dopant from the front surface of the semiconductor wafer while the back surface of the semiconductor wafer is held by a holding apparatus via the protective tape.

According to the disclosure above, no dents, contamination, or the like occur at the back surface of the semiconductor wafer, whereby the rate of conforming products may be improved for the semiconductor device. Further, the first ion-implantation process may be performed without the use of costly wafer supports such as a glass support, whereby costs may be reduced.
(2) Further, in the method of manufacturing the semiconductor device according to the present disclosure, in (1) above, the first dopant ion-implanted in the first ion-implantation process constitutes a lifetime killer. The method further includes, as a removal process after the first ion-implantation process, removing the protective tape from the back surface of the semiconductor wafer. The method further includes, as an electrode process, forming a back electrode at the back surface of the semiconductor wafer. The method further includes, as a heating process, performing a heat treatment, thereby forming an ohmic contact between the semiconductor wafer and the back electrode. The heating process may also serve as a generation process for generating the lifetime killer from the first dopant.

According to the disclosure above, manufacturing processes may be simplified.
(3) Further, in the method of manufacturing the semiconductor device according to the present disclosure, in (1) or (2) above, the back surface process includes performing a second ion implantation process of ion-implanting a second dopant from the back surface of the semiconductor wafer, thereby forming a diffused region of a predetermined conductivity type, the diffused region configuring the back-surface device structure. The first ion-implantation process may be performed using the ion implantation equipment used for the second ion implantation process.

According to the disclosure described above, the first ion-implantation process may be performed using existing ion implantation equipment, whereby costs may be reduced.
(4) Further, in the method of manufacturing the semiconductor device according to the present disclosure, in any one of (1) to (3) above, the holding apparatus may be a stage of the ion implantation equipment.

According to the disclosure described above, the first ion-implantation process may be performed using existing ion implantation equipment, whereby costs may be reduced.
(5) Further, in the method of manufacturing the semiconductor device according to the present disclosure, in any one of (1) to (4) above, a securing apparatus that secures the semiconductor wafer may be built into the holding apparatus and the holding apparatus may secure and hold the back surface of the semiconductor wafer by the securing apparatus, via the protective tape.

According to the disclosure described above, the first ion-implantation process may be performed by existing ion implantation equipment, whereby costs may be reduced.
(6) Further, in the method of manufacturing the semiconductor device according to the present disclosure, in any one of (1) to (5) above, the back surface of the semiconductor wafer includes a center portion and an outer peripheral portion that has a predetermined width and surrounds a periphery of the center portion and in the grinding process, the center portion is ground. The outer peripheral portion of the semiconductor wafer is left to be thicker than the center portion. In the protecting process, the protective tape may be applied to the back surface of the semiconductor wafer, from the center portion to the outer peripheral portion.

According to the disclosure described above, even in an instance in which the outer peripheral portion of the semiconductor wafer has a rib-like shape and the strength of the semiconductor wafer is increased, the protective tape may be removed from the semiconductor wafer using an existing removal method.

Findings underlying the present disclosure are discussed. As a method of manufacturing a semiconductor device of a reference example, for example, as described in Japanese Laid-Open Patent Publication No. 2015-207733, a semiconductor wafer in which a front-surface device structure has been formed is ground from a back surface of the semiconductor wafer (back surface grinding (back grinding)) thereby reducing a thickness of the semiconductor wafer and subsequently, predetermined regions are formed in the semiconductor wafer (at the back surface thereof) by ion implantation of a dopant of a predetermined conductivity type. A semiconductor device having the predetermined regions that are provided in the semiconductor wafer (at the back surface thereof) may be, for example, a reverse conducting insulated gate bipolar transistor (RC-IGBT) in which a vertical IGBT and a vertical diode constituting a free-wheeling diode (FWD) are both provided on a single semiconductor substrate (semiconductor chip).

In the RC-IGBT, in the semiconductor substrate (at the front surface thereof), a MOS gate (metal oxide semiconductor field effect transistor: insulated gate with a metal-oxide-semiconductor three-layer structure) structure of the IGBT is formed; a p-type base region further serves as a p-type anode region of the FWD; and a p-type collector region of the IGBT and an n-type cathode region of the FWD are selectively formed in the semiconductor substrate (at the back surface thereof) by ion-implantation of a dopant of a predetermined conductivity type. During forward bias when voltage that is positive relative to a front side of the semiconductor substrate is applied to a back side of the semiconductor substrate, current flows between an emitter and collector of the IGBT and during reverse bias when current that is negative relative to the front side of the semiconductor substrate is applied to the back side of the semiconductor substrate, the FWD conducts and forward current flows through the FWD.

Further, in the RC-IGBT, to adjust the characteristics of the IGBT or the FWD, after the back surface grinding of the semiconductor wafer, a dopant constituting a carrier lifetime killer is ion-implanted from the front surface of the semiconductor wafer. At this time, warpage occurring in the semiconductor wafer during the back surface grinding has to be forcibly repaired to increase the flatness of the semiconductor wafer. For example, the back surface of the semiconductor wafer is attached to the wafer stage by suction whereby the flatness of the semiconductor wafer may be increased, however, when the back surface of the semiconductor wafer is in direct contact with the wafer stage, dents that penetrate through the back-surface device structure (the p-type collector region and the n-type cathode region), contamination by adhered foreign particles, etc. occur at the back surface of the semiconductor wafer, whereby the rate of conforming products for the semiconductor device decreases.

Improvement of the rate of conforming products for a semiconductor device is one example of a problem solved by the present embodiment.

Embodiments of a method of manufacturing a semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

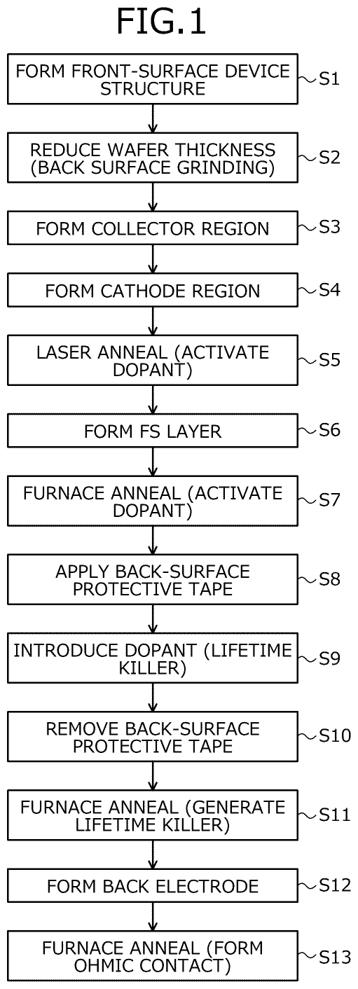

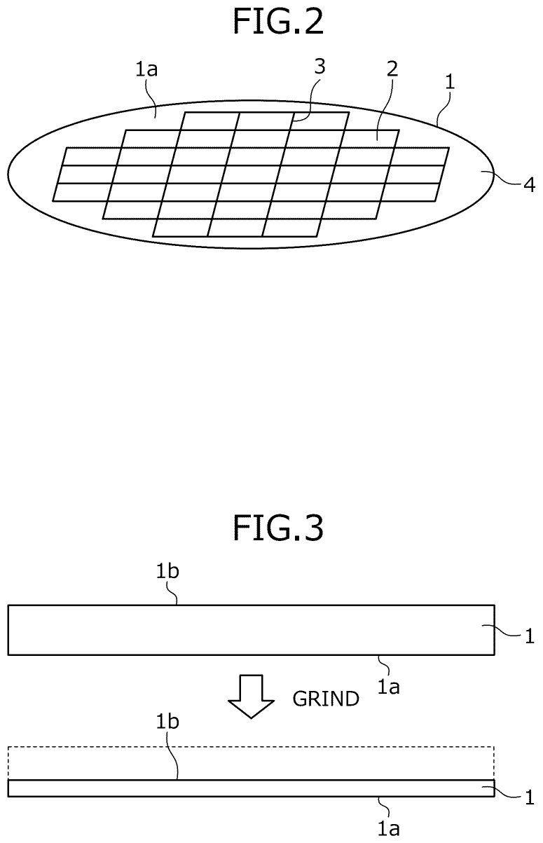

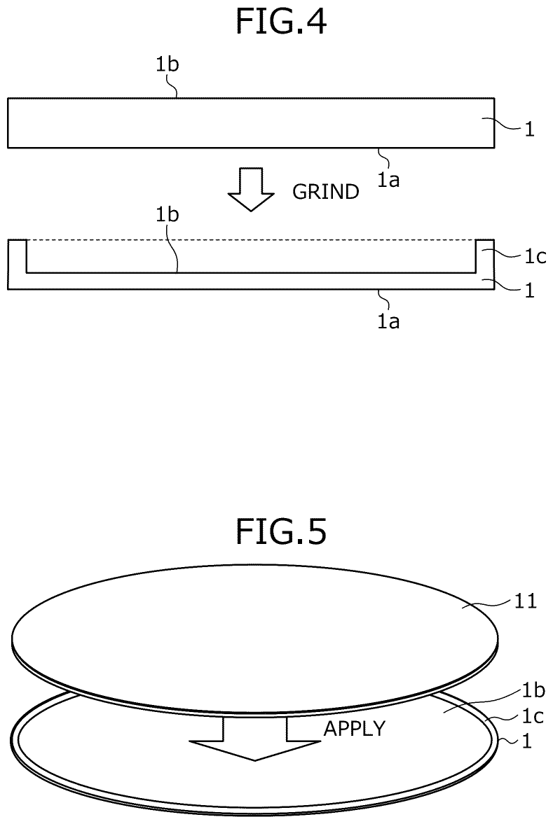

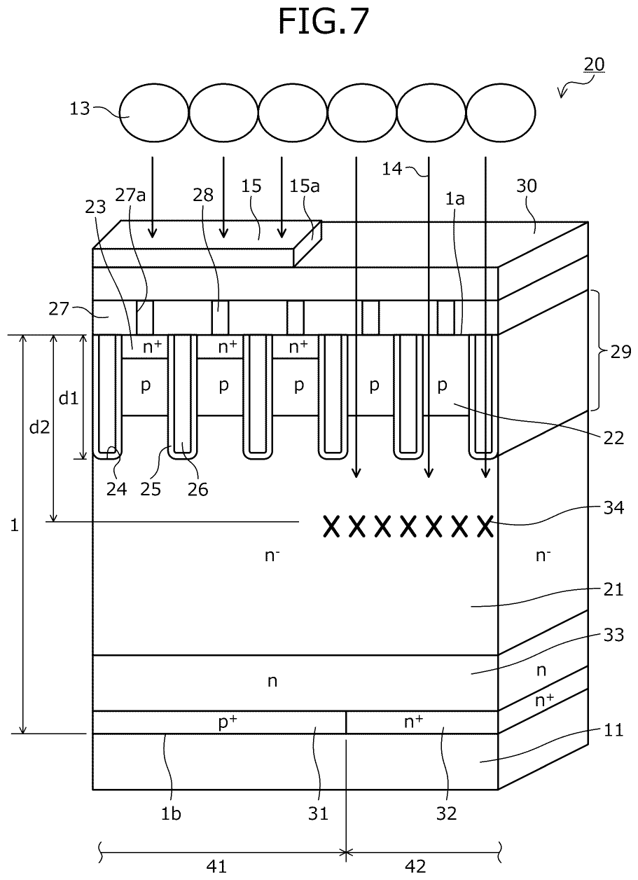

A method of manufacturing a semiconductor device according to an embodiment solving the problems above is described. FIG. 1 is a flowchart showing an outline of the method of manufacturing the semiconductor device according to the embodiment. FIGS. 2, 5, 6, 7, and 8 are perspective views depicting states of the semiconductor device during manufacture according to the embodiment. FIGS. 3, 4, and 9 are cross-sectional views depicting states of the semiconductor device during manufacture according to the embodiment. FIGS. 3 and 4 depict examples of different processes at step S2 in FIG. 1. A structure of a RC-IGBT in which an IGBT and a FWD are built on a single semiconductor substrate is depicted in FIG. 7 as an example of a semiconductor device 20 fabricated (manufactured) by the method of manufacturing the semiconductor device according to the embodiment.

First, as depicted in FIG. 2, in a semiconductor wafer 1, at a front surface (first main surface) 1a thereof, a front-surface device structure is formed in each of multiple chip regions 2 (step S1: front surface process). A diameter of the semiconductor wafer 1 is, for example, in a range of about 200 mm (about 8 inches) to about 300 mm. A semiconductor material of the semiconductor wafer 1 may be silicon (Si) or silicon carbide (SiC). A front-surface device structure is a MOS gate structure 29 (refer to FIG. 7), an interlayer insulating film 27 (refer to FIG. 7), a front electrode 30, a passivation film (not depicted). The chip regions 2 are regions cut from the semiconductor wafer 1 into individual chips (semiconductor chips).

Each of the chip regions 2 has a substantially rectangular shape in a plan view and the chip regions 2 are disposed in a matrix-like pattern in substantially a center of the semiconductor wafer 1. In the passivation film, openings respectively exposing scribing regions (dicing lines) 3 and an electrode pad (later-described emitter electrode 30), etc. may be formed. The scribing regions 3 are regions between the chip regions 2 and surround peripheries of the chip regions 2. The chip regions 2 include outermost ones that are closest to an end of the semiconductor wafer 1 and between an end of the semiconductor wafer 1 and the outermost ones is a non-operating region 4 that is not used as a semiconductor chip and, for example, as described later, when an outer peripheral portion 1c of the semiconductor wafer 1 (refer to FIG. 4) has a rib-like shape, a corresponding rib portion (the outer peripheral portion 1c) is in the non-operating region 4.

Next, as depicted in FIGS. 3 and 4, the semiconductor wafer 1, from a back surface (second main surface) 1b thereof, is ground (back surface grinding (back grinding)), thereby, reducing a thickness of the semiconductor wafer 1 to a product thickness used for the semiconductor device 20 (step S2: grinding process). In the process at step S2, the semiconductor wafer 1 may be formed into a flat plate-like shape with a thickness that has been reduced uniformly to the product thickness across the entire surface (FIG. 3). Further, in the process at step S2, only the center portion of the semiconductor wafer 1 may be reduced to the product thickness while the outer peripheral portion 1c of a predetermined width is left thicker than the center portion, thereby forming a rib-like shape (FIG. 4). The rib portion (the outer peripheral portion 1c), which remains relatively thick along the outer periphery of the semiconductor wafer 1 may increase the strength of the semiconductor wafer 1.

Next, a p-type dopant (second dopant) is ion-implanted from the back surface 1b of the semiconductor wafer 1, thereby forming, in an entire area of the back surface 1b of the semiconductor wafer 1, a p⁺-type collector region 31 (back-surface device structure, refer to FIG. 7) of the IGBT (step S3: back surface process, second ion implantation process). Next, an ion implantation mask (not depicted) opened at a portion thereof corresponding to a formation region of an n⁺-type cathode region 32 (back-surface device structure, refer to FIG. 7) of the FWD is formed at the back surface 1b of the semiconductor wafer 1. Next, an n-type dopant (second dopant) is ion-implanted from the back surface 1b of the semiconductor wafer 1 using the ion implantation mask, thereby inverting a portion of the p⁺-type collector region 31 to an n-type and selectively forming the n⁺-type cathode region 32 (step S4: back surface process, second ion implantation process).

Next, regions of the semiconductor wafer 1 (at the back surface 1b thereof) are selectively heated (laser anneal) by laser irradiation from the back surface 1b of the semiconductor wafer 1 (step S5: back surface process). In the process at step S5, the dopants ion-implanted in the processes at steps S3 and S4 are electrically activated. In the process at step S5, instead of laser anneal, the entire semiconductor wafer 1 may be heated by a heat treatment furnace (furnace anneal) and thereby electrically activating the dopants. Further, the process at step S5 may be omitted and a later-described process (furnace anneal) at step S7 may serve as the process at step S5.

Next, an n-type dopant (second dopant) is ion-implanted from the back surface 1b of the semiconductor wafer 1 thereby forming an n-type field stop (FS) layer 33 (back-surface device structure, refer to FIG. 7) at a position deeper from the back surface 1b of the semiconductor wafer 1 than are the p⁺-type collector region 31 and the n⁺-type cathode region 32 (step S6: back surface process, second ion implantation process). In the processes at steps S3 to S6, the semiconductor wafer 1 is placed on (or attached to) the stage of general semiconductor manufacturing equipment (ion implantation equipment, laser anneal equipment) with the back surface 1b (surface under processing) facing upward (facing away from the stage). Thus, the front surface 1a of the semiconductor wafer 1 may be protected by a resist film or a glass support (glass substrate functioning as a wafer support) before the process at step S3.

Next, the resist film (or glass support) at the front surface 1a of the semiconductor wafer 1 is removed (glass support is peeled) and thereafter, the semiconductor wafer 1 is inserted into a heat treatment furnace and the entire semiconductor wafer 1 is heated (furnace anneal) (step S7: back surface process). In the process at step S7, the dopant ion-implanted by the process at step S6 is electrically activated. Heating conditions for the process at step S7 are set to a level such that structures (front-surface device structure, the p⁺-type collector region 31, the n⁺-type cathode region 32) formed in the semiconductor wafer 1 may withstand (are not destroyed by) the heating. In particular, the heating temperature in the process at step S7 may be, for example, about 400 degrees C.

Next, as depicted in FIG. 5, a back-surface protective tape 11 is applied to the back surface 1b of the semiconductor wafer 1 (step S8: protecting process). In an instance in which the semiconductor wafer 1 has a flat plate-like shape (refer to FIG. 3) and in an instance in which the outer peripheral portion 1c of the semiconductor wafer 1 has a rib-like shape (refer to FIG. 4), preferably, the entire back surface 1b of the semiconductor wafer 1 may be covered and protected by the back-surface protective tape 11 (FIG. 5 depicts an instance in which the outer peripheral portion 1c of the semiconductor wafer 1 has a rib-like shape). When the outer peripheral portion 1c of the semiconductor wafer 1 has a rib-like shape, the back-surface protective tape 11 is applied covering the back surface 1b of the semiconductor wafer 1, from the center portion to the outer peripheral portion 1c, whereby, for example, in the outer peripheral portion 1c of the semiconductor wafer 1, a portion that is to be held when the back-surface protective tape 11 is removed may be formed and the back-surface protective tape 11 may be removed using an existing technique.

The back-surface protective tape 11 is an adhesive tape with a typical layered structure in which an adhesive is applied to a substrate material layer, thereby forming an adhesive layer, the surface of which constitutes the adhesive surface. The substrate material layer of the back-surface protective tape 11 is a support that holds the adhesive layer and has heat resistance, chemical resistance, and strength to withstand the manufacturing processes after the process at step S8. Materials generally used for the substrate material layer of adhesive tapes, such as polyethylene naphthalate (PEN), polyimides (PI), polyolefin (PO), special polyesters, and special resins, have sufficient heat resistance, chemical resistance, and strength to withstand general manufacturing processes; therefore, any of these materials may be used for the substrate material layer of the back-surface protective tape 11. The adhesive layer of the back-surface protective tape 11 has heat resistance and chemical resistance to withstand the manufacturing processes after the process at step S8.

In particular, preferably, the materials of the substrate material layer of the back-surface protective tape 11 and the adhesive layer may be suitably selected with particular consideration of the heat resistance (for example, maximum heat resistance of about 200 degrees C.) during a later-described process at step S9. A reason for this is that, as described above, a material of a typical substrate material layer that can be used for the substrate material layer of the back-surface protective tape 11 has sufficient heat resistance and thus, the heat resistance of the back-surface protective tape 11 is assumed to be determined by the heat resistance of the adhesive layer. In particular, the inventors experimentally confirmed that, for example, a protective tape for protecting a main surface of the semiconductor wafer 1 during a plating treatment for forming a plating film on an electrode pad may be diverted for use as the back-surface protective tape 11. In addition to this, a heat-resistant tape for protecting a main surface of the semiconductor wafer 1 during various manufacturing processes in which heat stress is applied may be diverted.

Further, the back-surface protective tape 11 has a function of forcibly correcting warpage that occurs in the semiconductor wafer 1 before the process at step S8, whereby the flatness of the semiconductor wafer 1 is increased. Further, the back-surface protective tape 11 functions as a wafer support reinforcing the semiconductor wafer 1 during transport of the semiconductor wafer 1 and during manufacturing processes after the process at step S8, thereby, suppressing warpage and breakage of the semiconductor wafer 1. Further, in manufacturing processes after the process at step S8, heat generated in the semiconductor wafer 1 is dissipated externally from stages of various types of semiconductor manufacturing equipment, via the back-surface protective tape 11, whereby the semiconductor wafer 1 is cooled.

Qualitatively, as the thickness (total thickness of the thickness of the substrate material layer and the thickness of the adhesive layer) of the back-surface protective tape 11 increases, the effect of the back-surface protective tape 11 as a wafer support increases, however, the back-surface protective tape 11 also tends to retain heat, whereby the cooling efficiency of the semiconductor wafer 1 decreases. On the other hand, as the thickness of the back-surface protective tape 11 decreases, the cooling efficiency of the semiconductor wafer 1 increases. Thus, preferably, the thickness of the back-surface protective tape 11 is set so that the wafer support effect of the back-surface protective tape 11 and the cooling efficiency of the semiconductor wafer 1 are suitably obtained. In particular, preferably, the thickness of the back-surface protective tape 11 is assumed to be, for example, in a range of about 40 μm to 200 μm.

Further, when the diameter of the semiconductor wafer 1 is large, typically, after the process (formation of the front-surface device structure) at step S1, the process (back surface grinding of the semiconductor wafer 1) at step S2 and the processes (back-side processes) at steps S3 to S6 are performed with the semiconductor wafer 1 being reinforced by a glass support applied to the front surface 1a of the semiconductor wafer 1. Assuming an instance in which, in the process at step S8, the semiconductor wafer 1 is reinforced using a glass support that protects the front surface 1a of the semiconductor wafer 1, the glass support is removed from the front surface 1a of the semiconductor wafer 1 and is applied to the back surface 1b of the semiconductor wafer 1.

When the glass support is removed from the front surface 1a of the semiconductor wafer 1, the semiconductor wafer 1 is thin due to the back surface grinding and thus, becomes warped. The larger is the diameter of the semiconductor wafer 1, the greater is the warpage of the semiconductor wafer 1 and thus, after the glass support is removed from the front surface 1a of the semiconductor wafer 1, applying the glass support to the back surface 1b of the semiconductor wafer 1 is difficult. When the diameter of the semiconductor wafer 1 is 300 mm, even when the outer peripheral portion 1c of the semiconductor wafer 1 is left thicker than the center portion, thereby increasing the strength of the semiconductor wafer 1 (refer to FIG. 4), warpage of the semiconductor wafer 1 is large.

Furthermore, when a glass support is used in the process at step S8, the number of times that the glass support is applied and removed increases and thus, manufacturing cost increases. For example, each time the glass support is applied and removed, a cost of about 1000 Japanese yen is incurred. In addition, the glass support itself is costly. On the other hand, in the embodiment, the back-surface protective tape 11 is used as a wafer support and thus, as compared to a case in which a glass support is used, application to the semiconductor wafer 1 is easy and cost is reduced. For example, the cost incurred with the process at step S8 and the process at later-described step S10 is about a few tens of Japanese yen.

Further, in the process at step S8, while the back surface 1b of the semiconductor wafer 1 may be protected by an organic material film such as a resist, in an instance in which a resist mask 15 (refer to FIG. 7) is formed at the front surface 1a of the semiconductor wafer 1 during the process at later-described step S9, developing solution, rinsing solution, etc. used during the formation of the resist mask 15 may reach the back surface 1b of the semiconductor wafer 1 and possibly cause the organic material film at the back surface 1b of the semiconductor wafer 1 to peel or be removed. On the other hand, in the embodiment, the back surface 1b of the semiconductor wafer 1 is protected by the back-surface protective tape 11, whereby exposure of the back surface 1b of the semiconductor wafer 1 during formation of the resist mask 15 may be prevented.

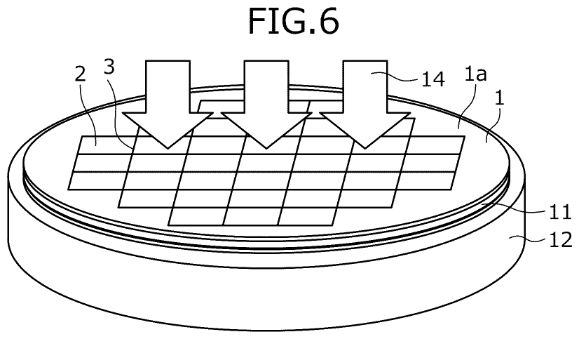

Next, as depicted in FIG. 6, the semiconductor wafer 1 is placed on a stage (holding apparatus) 12 of ion implantation equipment, with the front surface 1a (surface under processing) facing up (away from the stage 12). Further, a securing apparatus, such as an electrostatic chuck built into the stage 12, secures an entire area (substantially the entire surface of the center portion of the back surface 1b and the outer peripheral portion 1c even when the outer peripheral portion 1c of the semiconductor wafer 1 has a rib-like shape) of the back surface 1b of the semiconductor wafer 1 to the stage 12, via the back-surface protective tape 11, whereby the semiconductor wafer 1 is held to the stage 12. The back surface 1b of the semiconductor wafer 1 is not in direct contact with the stage 12 and thus, dents, contamination, etc. due to foreign matter on the stage 12 do not occur at the back surface 1b of the semiconductor wafer 1.

Next, as depicted in FIGS. 6 and 7, an ion-implantation 14 of a dopant (first dopant) 13 constituting a carrier lifetime killer (lattice defects) 34 is performed from the front surface 1a of the semiconductor wafer 1 (step S9: first ion-implantation process). At this time, while the ion-implantation 14 of the dopant 13 increases the temperature of the semiconductor wafer 1, the entire area of the back surface 1b of the semiconductor wafer 1 is secured to the stage 12 via the back-surface protective tape 11, whereby the temperature of the semiconductor wafer 1 is maintained to be uniform across the surface of the semiconductor wafer 1 while the semiconductor wafer 1 is cooled from the back surface 1b by the stage 12 and in this state, the ion-implantation 14 of the dopant 13 may be performed at the front surface 1a of the semiconductor wafer 1.

The inventors confirmed experimentally that even when the back-surface protective tape 11 intervenes between the stage 12 and the semiconductor wafer 1, the semiconductor wafer 1 can be cooled from the back surface 1b by the stage 12. Further, the entire area of the back surface 1b of the semiconductor wafer 1 is secured to the stage 12 via the back-surface protective tape 11, whereby warpage of the semiconductor wafer 1 is forcibly corrected and the flatness of the semiconductor wafer is increased. As a result, the lifetime killer (in FIG. 7, indicated by “x”) 34 may be introduced at a constant depth d2 from the front surface 1a of the semiconductor wafer 1, across an entire area of an introduction region for the lifetime killer 34 by the ion-implantation 14 of the dopant 13.

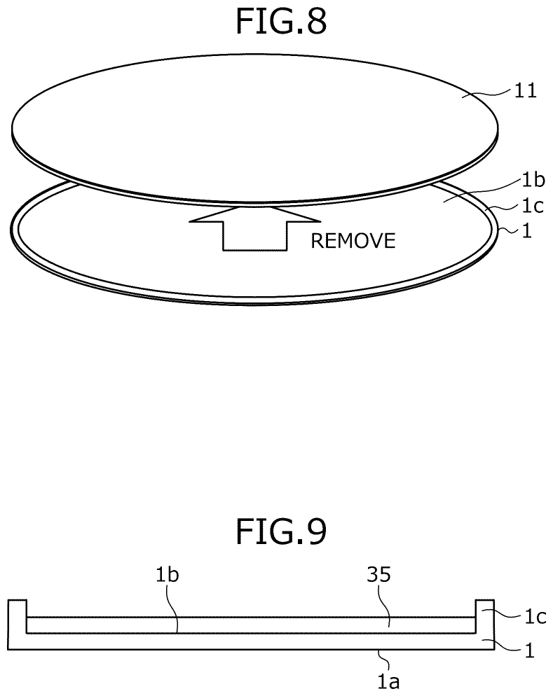

For example, the MOS gate structure 29 (i.e., bottoms of trenches 24) of a trench gate type IGBT reaches, for example, a depth d1 of about 5 μm at maximum from the front surface 1a of the semiconductor wafer 1. Thus, preferably, the depth d2 of the lifetime killer 34 is closer to the back surface 1b of the semiconductor wafer 1 than are the bottoms of the trenches 24 inside an n-type drift region 21 and positioned at a depth of not more than 20 μm from the front surface 1a of the semiconductor wafer 1. Further, as depicted in FIG. 8, the back-surface protective tape 11 is removed from the back surface 1b of the semiconductor wafer 1 using an existing removal method (step S10: removal process).

In the process at step S9, in an instance in which the lifetime killer 34 is selectively introduced, the resist mask 15, which is opened at a portion corresponding to the introduction region of the lifetime killer 34, is formed at the front surface 1a of the semiconductor wafer 1 after the process at step S7 but before the process at step S8 and the ion-implantation 14 of the dopant 13 is performed in an opening 15a of the resist mask 15 (refer to FIG. 7). Further, the resist mask 15 suffices to be removed (ashing) after the process at step S10 but before the process at step S11. FIG. 7 depicts a state in which the lifetime killer 34 is introduced in an entire area of a FWD region 42 and in a portion of an IGBT region 41, the portion being near a border with the FWD region 42.

Further, preferably, manufacturing processes (front-side processes) for the front surface 1a of the semiconductor wafer 1 may be performed during the process of step S1 as far as possible. A reason for this is that dents and contamination occurring at the back surface 1b of the semiconductor wafer 1 during the process of step S1 may be removed by the process (back surface grinding of the semiconductor wafer 1) of step S2. When the process of step S9 is performed before the process of step S2, the dopant 13 implanted by the ion-implantation 14 in the process of step S9 is electrically activated by the processes of steps S5 and S7 thereafter and the lifetime killer 34 is not generated (or disappears).

Even when a region of the back surface 1b of the semiconductor wafer 1 is locally heated by laser anneal like that in the process of step S5, heat by the laser anneal is transmitted from the back surface 1b of the semiconductor wafer 1 to the front surface 1a and thus, the dopant 13 implanted in the semiconductor wafer 1 (at the back surface 1b thereof) by the ion-implantation 14 is electrically activated. Therefore, the process of step S9 has to be performed after the processes of steps S3 to S7 (i.e., after formation of diffused regions of the back surface 1b of the semiconductor wafer 1 by ion implantation). Thus, during the process at step S9, it becomes necessary to prevent dents and contamination from occurring at the back surface 1b of the semiconductor wafer 1.

In the present embodiment, the back surface 1b of the semiconductor wafer 1 is covered with and protected by the back-surface protective tape 11, whereby even when the process of step S9 is performed after the manufacturing processes (back-side processes) for the back surface 1b of the semiconductor wafer 1, the back surface 1b of the semiconductor wafer 1 is not in direct contact with the stage 12. Therefore, the process of step S9 may be performed using the existing ion implantation equipment used in the processes of steps S1, S3, S4, and S6, after the back-side processes. Further, since there is no need for implantation equipment equipped with a special holding apparatus for clamping and holding the end of the semiconductor wafer 1, there is no need for capital investment and costs may be reduced.

The semiconductor device 20 fabricated on the semiconductor wafer 1 may be of a low breakdown voltage class (not more than 1200V) and the lower is the breakdown voltage class, the thinner is the semiconductor wafer 1 and thus, the heat generated by the laser anneal during the process at step S5 is easily transmitted from the back surface 1b side of the semiconductor wafer 1 to the front surface 1a side thereof. For example, in an instance in which the breakdown voltage class of the semiconductor device 20 is 1200V, the thickness of the semiconductor wafer 1 is not more than about 120 μm. In an instance in which the breakdown voltage class of the semiconductor device 20 is 600V, the thickness of the semiconductor wafer 1 is about 60 μm. Therefore, the present method of manufacturing the semiconductor device according to the embodiment is particularly useful for the semiconductor device 20 of a low breakdown voltage class.

Next, the semiconductor wafer 1 is inserted into a heat treatment furnace and the entire semiconductor wafer 1 is heated (furnace anneal) (step S11: generation process). The dopant 13 implanted in the semiconductor wafer 1 by the ion-implantation 14 in the process at step S10 forms a deep level in the band gap (forbidden energy gap) by the process at step S11 and the lifetime killer 34 is generated. Preferably, the process at step S11 may be performed under a condition of a temperature that is as high as possible without electrically activating the dopant 13. In particular, in the process at step S11, the heating temperature may be in a range of, for example, about 300 degrees C. to 400 degrees C.

Next, as depicted in FIG. 9, a surface electrode (back electrode) 35 is formed at the back surface 1b of the semiconductor wafer 1 (step S12: electrode process). FIG. 9 depicts an instance in which the back electrode 35 is formed on the semiconductor wafer 1 in which the outer peripheral portion 1c thereof has a rib-like shape. During the process at step S12, the front electrode 30 may also be formed. Next the semiconductor wafer 1 is inserted into a heat treatment furnace and the entire semiconductor wafer 1 is heated (furnace anneal) (step S13: heating process). In the process at step S13, the semiconductor wafer 1 is heated at a temperature not more than, for example, about 300 degrees C., thereby forming an ohmic contact between the back surface 1b of the semiconductor wafer 1 and the back electrode 35.

When the process at step S13 is performed at a temperature not more than 300 degrees C., warpage of the semiconductor wafer 1 may be suppressed. While warpage of the semiconductor wafer 1 increases the higher is the processing temperature at step S13, when the process at step S13 is performed by a temperature higher than 300 degrees C., the process of step S13 may serve as the process of step S11 and the process of step S11 may be omitted. In this instance, the back-surface protective tape 11 may be used as a wafer support up until just before the formation of the back electrode 35. Thereafter, the semiconductor wafer 1 is diced (cut) along the scribing regions 3 into the individual chip regions 2, whereby the semiconductor device 20 (semiconductor chip) is completed.

An example of the structure of the semiconductor device 20 fabricated by the method of manufacturing the semiconductor device according to the embodiment is described with reference to FIG. 7. The semiconductor device 20 fabricated by the method of manufacturing the semiconductor device according to the embodiment is an RC-IGBT on a semiconductor chip (one of the chip regions 2 diced from the semiconductor wafer 1), in which in an active region, the IGBT region 41 constituting an operating region of an IGBT and the FWD region 42 constituting an operating region of a FWD are provided adjacent to each other. The active region is a region through which a main current flows when the semiconductor device 20 is on and is disposed in substantially a center of the semiconductor chip.

Between the active region and an end of the semiconductor chip is an edge termination region. The edge termination region surrounds a periphery of the active region and has a function of relaxing electric field of the front side of the semiconductor chip and sustaining the breakdown voltage. In the edge termination region, a voltage withstanding structure such as a guard ring, a field limiting ring (FLR), and a junction termination extension (JTE) structure is disposed. The breakdown voltage is a voltage upper limit at which the device may be used without malfunctioning or being destroyed.

In the IGBT region 41, multiple unit cells (functional units of the device) of the IGBT are disposed adjacent to each other. In the FWD region 42, multiple unit cells of the FWD are disposed adjacent to each other. The IGBT of the IGBT region 41 and the FWD of the FWD region 42 are connected in antiparallel. The IGBT region 41 and the FWD region 42, for example, are disposed adjacently, repeatedly alternating with each other in a direction parallel to a front surface of the semiconductor chip. The front surface and the back surface of the semiconductor chip correspond, respectively, to the front surface 1a and the back surface 1b of the semiconductor wafer 1 (refer to FIG. 2).

A portion of the semiconductor chip excluding the MOS gate structure 29, the p⁺-type collector region 31, the n⁺-type cathode region 32, and the n-type FS layer 33 constitutes the n-type drift region 21. The MOS gate structure 29, the p⁺-type collector region 31, the n⁺-type cathode region 32, and the n-type FS layer 33 are formed, respectively, by the processes at steps S1, S3, S4, and S6 of the method of manufacturing the semiconductor device according to the embodiment (refer to FIG. 1). The MOS gate structure 29 is configured by a p-type base region 22, n⁺-type emitter regions 23, p⁺⁺-type contact regions (not depicted), the trenches 24, gate insulating films 25, and gate electrodes 26.

The p-type base region 22 is provided in the active region, between the front surface of the semiconductor chip and the n⁺-type drift region 21, the p-type base region 22 being in contact with the n-type drift region 21. The p-type base region 22 is provided in an entire area of the active region, spanning the IGBT region 41 and the FWD region 42. The p-type base region 22 functions as a p-type anode region of the FWD in the FWD region 42. The n⁺-type emitter regions 23 and the p⁺⁺-type contact regions are each selectively provided in the IGBT region 41, between the front surface of the semiconductor chip and the p-type base region 22, the n⁺-type emitter regions 23 and the p⁺⁺-type contact regions each being in contact with the p-type base region 22.

The FWD region 42 is free of the n⁺-type emitter regions 23. The p⁺⁺-type contact regions may be omitted. In this instance, instead of the p⁺⁺-type contact regions, the p-type base region 22 reaches the front surface of the semiconductor chip. In the IGBT region 41, the trenches 24 penetrate through the n⁺-type emitter regions 23 and the p-type base region 22 in a depth direction from the front surface of the semiconductor chip and terminate in the n-type drift region 21. In the FWD region 42, the trenches 24 penetrate through the p-type base region 22 in the depth direction from the front surface of the semiconductor chip and terminate in the n⁺-type drift region 21.

The gate electrodes 26 are provided in the trenches 24 via the gate insulating films 25, respectively. In the n-type drift region 21, the lifetime killer 34 is introduced at the depth d2 in a range not more than 20 μm from the front surface of the semiconductor chip and closer to the back surface of the semiconductor chip than are the bottoms of the trenches 24. The lifetime killer 34, for example, may be introduced only in the FWD region 42 or may introduced in an entire area (the IGBT region 41 and the FWD region 42) of the active region. The lifetime of minority carriers (holes) of the n-type drift region 21 is shortened by the portion in which the lifetime killer 34 is introduced.

The interlayer insulating film 27 is provided in substantially the entire area of the front surface of the semiconductor chip and covers the gate electrodes 26. Multiple contact holes 27a that penetrate through the interlayer insulating film 27 in the depth direction are provided in the IGBT region 41 and the FWD region 42. Contacts 28 are provided in the contact holes 27a. The contacts 28 each have, for example, a barrier metal in ohmic contact with the front surface of the semiconductor chip and a contact plug that is on the barrier metal and embedded in the contact hole 27a.

In the IGBT region 41, the contacts 28 are in contact with the n⁺-type emitter regions 23 and the p⁺⁺-type contact regions while in the FWD region 42, the contacts 28 are in contact with the p-type base region 22. On the interlayer insulating film 27 and the contacts 28, the front electrode 30 is provided in the entire area of the active region. The front electrode 30 is electrically connected to the p-type base region 22, the n⁺-type emitter regions 23, and the p⁺⁺-type contact regions, via the contacts 28. The front electrode 30 is the emitter electrode of the IGBT and also serves as an anode electrode of the FWD.

The p⁺-type collector region 31, the n⁺-type cathode region 32, and the n-type FS layer 33 are each provided between the back surface of the semiconductor chip and the n⁺-type drift region 21. The p⁺-type collector region 31 is provided in the IGBT region 41, in an entire area between the back surface of the semiconductor chip and the n⁺-type drift region 21. The n⁺-type cathode region 32 is provided in the FWD region 42, in an entire area between the back surface of the semiconductor chip and the n-type drift region 21. The p⁺-type collector region 31 and the n⁺-type cathode region 32 are adjacent to each other in a direction parallel to the back surface of the semiconductor chip.

The n-type FS layer 33 is provided between the back surface of the semiconductor chip and, the p⁺-type collector region 31 and the n⁺-type cathode region 32. The n-type FS layer 33 may be omitted. The back electrode 35 (refer to FIG. 9) is provided in the entire area of the back surface of the semiconductor chip. The back electrode 35 is formed by the process at step S12 of the method of manufacturing the semiconductor device according to the embodiment. The back electrode 35 is in contact with and electrically connected to the p⁺-type collector region 31 and the n⁺-type cathode region 32. The back electrode 35 is a collector electrode and also serves as a cathode electrode of the FWD.

As described, according to the embodiments, the thickness of the semiconductor wafer on which a front-surface device structure is formed is reduced and thereafter, predetermined regions are formed in the semiconductor wafer, at the back surface thereof, by ion implantation of a dopant of a predetermined conductivity type. Subsequently, the back-surface protective tape is applied to the back surface of the semiconductor wafer thereby protecting the back-surface device structure and while the back surface of the semiconductor wafer is held to the stage via the back-surface protective tape, the first dopant is ion-implanted from the front surface of the semiconductor wafer. At this time, the back surface of the semiconductor wafer does not directly contact the stage and thus, dents that penetrate through the back-surface device structure, contamination by adhered foreign matter, etc. do not occur at the back surface of the semiconductor wafer. Thus, the rate of conforming products for the semiconductor device may be improved.

In the foregoing, the present disclosure is not limited to the embodiments described above and various modifications within a range not departing from the spirit of the invention are possible. Further, in the embodiments, while a first conductivity type is assumed to be an n-type and a second conductivity type is assumed to be a p-type, the disclosure is similarly implemented with the first conductivity type is a p-type and the second conductivity type is an n-type.

The method of manufacturing a semiconductor device according to the present disclosure achieves an effect in that the rate of conforming products may be improved.

As described, the method of manufacturing a semiconductor device according to the present disclosure is useful for power semiconductor devices used in power converting equipment, power source devices of various types of industrial machines, etc. and is particularly suitable for semiconductor devices of a 1200V or lower breakdown voltage class.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a semiconductor device, the method comprising:
preparing a semiconductor wafer having a front surface and a back surface opposite to each other, and forming a front-surface device structure at the front surface;
grinding the semiconductor wafer from the back surface, thereby thinning the semiconductor wafer;
forming a back-surface device structure at the back surface of the semiconductor wafer after the grinding;
applying a protective tape to the back surface of the semiconductor wafer, thereby protecting the back-surface device structure; and
performing a first ion-implantation process of ion-implanting a first dopant from the front surface of the semiconductor wafer while the back surface of the semiconductor wafer is held by a holding apparatus via the protective tape.

2. The method according to claim 1, wherein
the first dopant constitutes a lifetime killer, and
the method further comprises:
after the performing the first ion-implantation process,
removing the protective tape from the back surface of the semiconductor wafer;
forming a back electrode at the back surface of the semiconductor wafer; and
performing a heat treatment, thereby forming an ohmic contact between the semiconductor wafer and the back electrode, and
generating the lifetime killer from the first dopant.

3. The method according to claim 1, wherein
the forming the back-surface device structure includes performing a second ion-implantation process of ion-implanting a second dopant from the back surface of the semiconductor wafer, thereby forming a diffused region of a predetermined conductivity type, the diffused region configuring the back-surface device structure, and
the first ion-implantation process and the second ion-implantation process are performed using a same ion implantation equipment.

4. The method according to claim 3, wherein the holding apparatus is a stage of the ion implantation equipment.

5. The method according to claim 1, wherein the holding apparatus includes a securing apparatus that secures and holds the back surface of the semiconductor wafer via the protective tape.

6. The method according to claim 1, wherein
the back surface of the semiconductor wafer includes a center portion and an outer portion of a predetermined width that surrounds a periphery of the center portion,
the grinding includes grinding the center portion of the back surface of the semiconductor wafer to thereby leave the outer portion thereof to be thicker than the center portion, and
the applying the protective tape includes applying the protective tape from the center portion to the outer portion of the back surface of the semiconductor wafer.
